(19) United States
(12) Patent Application Publication
(10) Pub. No.: US 2025/0237677 A1
(43) Pub. Date: Jul. 24, 2025

(54) CURRENT SENSOR AND METHOD OF MANUFACTURING CURRENT SENSOR

(71) Applicant: NEW POWER PLASMA CO., LTD., Suwon-si (KR)

(72) Inventors: Moon Que LEE, Seoul (KR); Seung-Jun PARK, Bucheon-si (KR); Jeong Hun PARK, Incheon (KR); Hae Been HAN, Seoul (KR); Hae-Chan HONG, Seoul (KR); Kook Young CHOI, Anyang-si (KR); Dong Won SHIN, Osan-si (KR); Kyu Tae HAN, Hwaseong-si (KR)

(21) Appl. No.: 19/034,700

(22) Filed: Jan. 23, 2025

(30) Foreign Application Priority Data
Jan. 23, 2024 (KR) 10-2024-0009979

(51) Int. Cl. G01R 15/18; G01R 33/00

(52) U.S. Cl. CPC G01R 15/181; G01R 33/0047; G01R 33/0052

(57) ABSTRACT

A current sensor includes: a printed circuit board (PCB) having a central hole that allows a conductor, which is a measurement target, to pass therethrough; a Rogowski coil part formed to be wound in a predetermined direction while keeping a predetermined distance from the central hole; and a shield part formed outside and inside the Rogowski coil part and configured to perform an electrical shielding function, and the shield part includes a shield bridge formed to connect separate spaces.

### CROSS-REFERENCE TO RELATED APPLICATION

This application claims priority to 35 USC 119 (a) of Korean Patent Application No. 10-2024-000009979, filed on 23 Jan. 2024 in the Korean Intellectual Property Office and the entire disclosures of which are incorporated herein by reference for all purposes.

### TECHNICAL FIELD

The present disclosure relates to a current sensor and a method of manufacturing the current sensor.

### BACKGROUND

A current sensor is a sensor configured to sense an alternating current (AC) and a direct current (DC). Methods of sensing a current may include, for example, a current transformer method of sensing a primary current by measuring a secondary current using a doughnut-shaped core on which primary and secondary coils are wound and a Hall element method of sensing the intensity of a magnetic field, i.e. the intensity of a current, by measuring a Hall voltage using a Hall element located in a magnetic field generated by the current.

A Rogowski coil is configured to measure a current by using a change in magnetic flux generated by a change in current. FIG. 1A is a plan view of a conventional Rogowski coil current sensor, and FIG. 1B is an example diagram illustrating a structure of the conventional Rogowski coil current sensor.

A conventional Rogowski coil current sensor 10, as shown in FIG. 1A, is a type of coil that is wound in the shape of a torus and is used for measuring a plasma current. Referring to FIG. 1A, the Rogowski coil current sensor 10 includes a hole 13 at its center to allow a measurement target to pass therethrough. A conductor 12 is wound around the outer circumference of the hole 13, and an insulator 11 is wound around the outer circumference of the conductor 12.

Referring to FIG. 1A and FIG. 1B, in the conventional Rogowski coil current sensor 10, a Rogowski coil 14 is wound around the outer circumference of the hole 13 at a predetermined distance from the hole 13. Further, the Rogowski coil 14 has a shield structure on its inner and outer walls. An outer wall shield 16 is located outside the Rogowski coil 14, and an inner wall shield 15 is located inside the Rogowski coil 14. Furthermore, a voltage sensing via wall 17 is placed between the inner wall shield 15 and the insulator 11.

However, in the conventional Rogowski coil current sensor 10, a via spacing of the inner wall shield 15 needs to be kept a predetermined distance or more. Therefore, the conventional Rogowski coil current sensor 10 can shield only low-frequency noise, but cannot shield high-frequency noise.

### SUMMARY

In view of the foregoing, the present disclosure is conceived to provide a current sensor capable of shielding high-frequency noise as well as low-frequency noise.

Also, the present disclosure is conceived to provide a current sensor which has an enhanced electrical shielding function.

The problems to be solved by the present disclosure are not limited to the above-described problems. There may be other problems to be solved by the present disclosure.

An aspect of the present disclosure provides a current sensor, including: a printed circuit board (PCB) having a central hole that allows a conductor, which is a measurement target, to pass therethrough; a Rogowski coil part formed to be wound in a predetermined direction while keeping a predetermined distance from the central hole; and a shield part formed outside and inside the Rogowski coil part and configured to perform an electrical shielding function, and the shield part includes a shield bridge formed to connect separate spaces.

Another aspect of the present disclosure provides a method of manufacturing a Rogowski coil current sensor, including: forming a printed circuit board (PCB) having a central hole that allows a conductor, which is a measurement target, to pass therethrough; forming a Rogowski coil part to be wound in a predetermined direction while keeping a predetermined distance from the central hole; and forming a shield part above, below, outside and inside the Rogowski coil part to perform an electrical shielding function, and the forming the shield part includes forming a shield bridge to connect separate spaces.

The above-described aspects are provided by way of illustration only and should not be construed as liming the present disclosure. Besides the above-described embodiments, there may be additional embodiments described in the accompanying drawings and the detailed description.

According to an embodiment of the present disclosure, it is possible to enhance an electrical shielding function by improving isolation between a current sensing unit and a voltage sensing unit compared to conventional technologies. Also, it is possible to provide a Rogowski coil current sensor capable of shielding high-frequency noise as well as low-frequency noise.

### BRIEF DESCRIPTION OF THE DRAWINGS

In the detailed description that follows, embodiments are described as illustrations only since various changes and modifications will become apparent to a person with ordinary skill in the art from the following detailed description. The use of the same reference numbers in different FIG.s indicates similar or identical items.

FIG. 1A is a plan view of a conventional Rogowski coil current sensor.

FIG. 1B is an example diagram illustrating a structure of the conventional Rogowski coil current sensor.

FIG. 2 illustrates a configuration of a Rogowski coil current sensor.

FIG. 3A is a plan view of a Rogowski coil current sensor including a first shield bridge.

FIG. 3B is an example diagram illustrating a structure of the Rogowski coil current sensor including the first shield bridge.

FIG. 4 is a cross-sectional view of the Rogowski coil current sensor including the first shield bridge.

FIG. 5 is an example diagram illustrating an upper opening surface and a lower opening surface.

FIG. 6A is a plan view of a Rogowski coil current sensor including a second shield bridge.

FIG. 6B is an example diagram illustrating a structure of the Rogowski coil current sensor including the second shield bridge.

FIG. 7A shows a PCB V-I sensor equivalent circuit, and FIG. 7B shows a simulation result.

FIG. 8A is an example diagram illustrating an electric field (E-field) of a Rogowski coil current sensor, and FIG. 8B is an example diagram illustrating a magnetic field (H-field) of the Rogowski coil current sensor.

FIG. 9 is a flowchart showing a method of manufacturing a Rogowski coil current sensor.

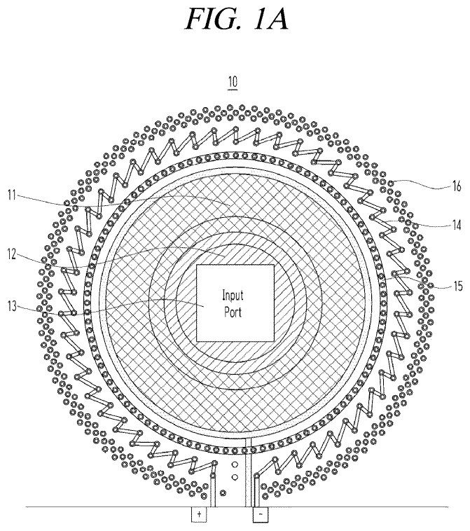

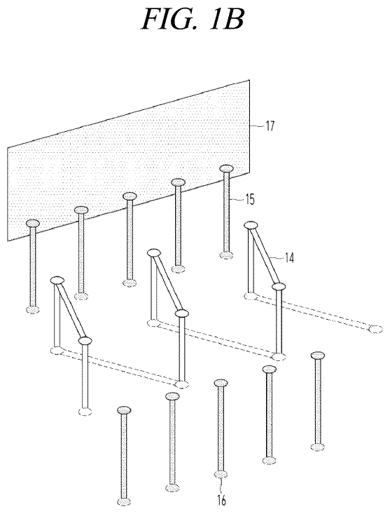

### DETAILED DESCRIPTION

Hereafter, example embodiments will be described in detail with reference to the accompanying drawings so that the present disclosure may be readily implemented by those skilled in the art. However, it is to be noted that the present disclosure is not limited to the example embodiments but can be embodied in various other ways. In the drawings, parts irrelevant to the description are omitted for the simplicity of explanation, and like reference numerals denote like parts through the whole document.

Throughout this document, the term “connected to” may be used to designate a connection or coupling of one element to another element and includes both an element being “directly connected” another element and an element being “electronically connected” to another element via another element. Further, it is to be understood that the terms “comprises,” “includes,” “comprising,” and/or “including” means that one or more other components, steps, operations, and/or elements are not excluded from the described and recited systems, devices, apparatuses, and methods unless context dictates otherwise; and is not intended to preclude the possibility that one or more other components, steps, operations, parts, or combinations thereof may exist or may be added.

Hereinafter, an embodiment of the present disclosure will be described in detail with reference to the accompanying drawings.

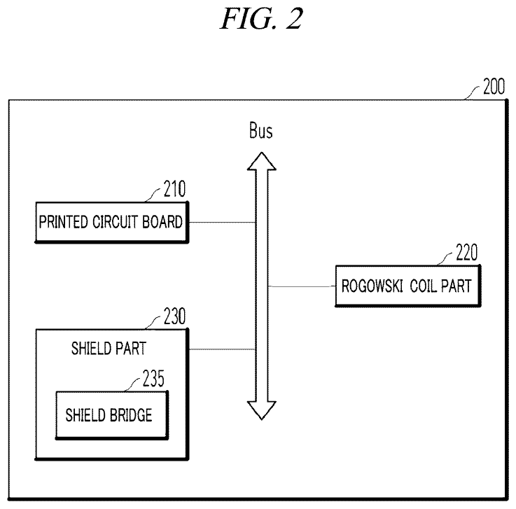

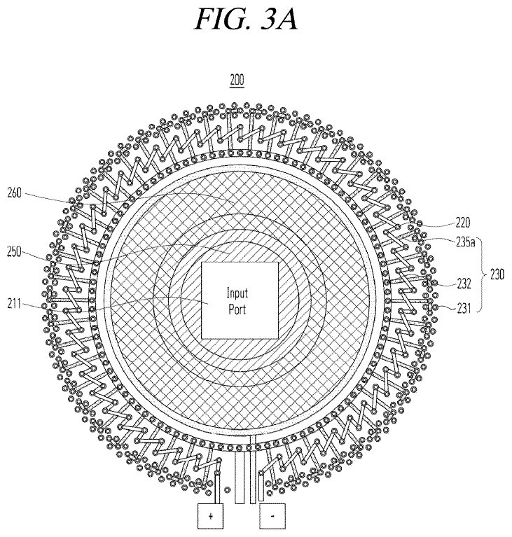

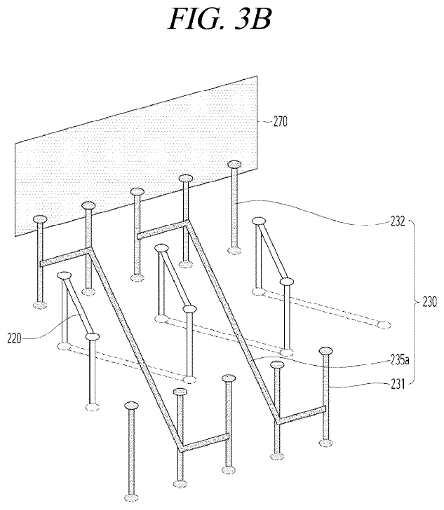

FIG. 2 illustrates a configuration of a Rogowski coil current sensor. Referring to FIG. 2, a Rogowski coil current sensor 200 according to the present disclosure may include a printed circuit board 210, a Rogowski coil part 220, a shield part 230, and a shield bridge 235. However, the above-described components 210 to 235 are examples of components that can be controlled by the Rogowski coil current sensor. Hereafter, a structure of the Rogowski coil current sensor according to the present disclosure will be described with reference to FIG. 3A to FIG. 6B.

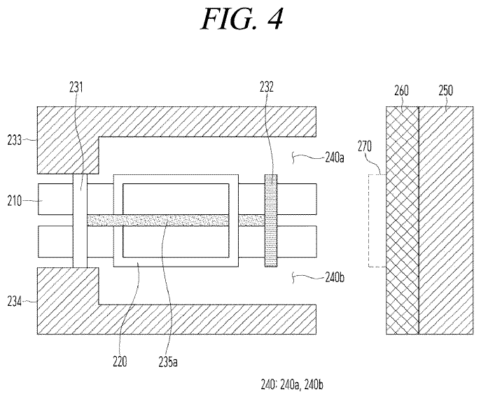

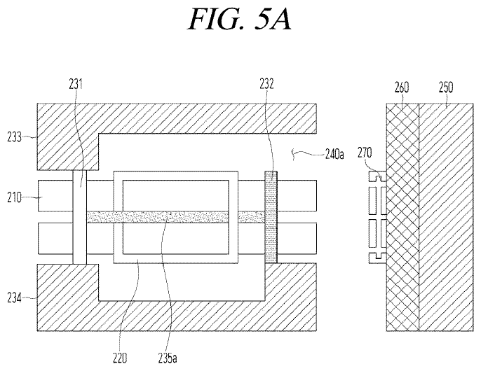

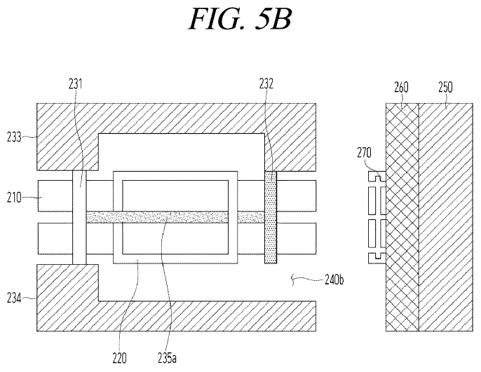

FIG. 3A is a plan view of a Rogowski coil current sensor including a first shield bridge, and FIG. 3B is an example diagram illustrating a structure of the Rogowski coil current sensor including the first shield bridge. FIG. 4 is a cross-sectional view of the Rogowski coil current sensor including the first shield bridge, and FIG. 5 is an example diagram illustrating an upper opening surface and a lower opening surface.

Referring to FIG. 3A, the printed circuit board (PCB) 210 of the Rogowski coil current sensor 200 has a central hole 211 that allows a conductor, which is a measurement target, to pass therethrough. A conductor 250 is located outside the central hole 211, and an insulator 260 is located outside the conductor 250. Further, the Rogowski coil part 220 is wound around the insulator 260.

The Rogowski coil part 220 is formed to be wound in a predetermined direction while keeping a predetermined distance from the central hole 211. Further, the shield part 230 that enables electrical shielding is formed outside and inside the Rogowski coil part 220.

The shield part 230 is formed outside and inside the Rogowski coil part 220 and performs an electrical shielding function. As shown in FIG. 3A and FIG. 3B, the shield part 230 includes an outer shield part 231 and an inner shield part 232. The outer shield part 231 is formed outside the Rogowski coil part 220, and the inner shield part 232 is formed inside the Rogowski coil part 220. Herein, the outer shield part 231 and the inner shield part 232 may be implemented as PCB vias. Furthermore, a voltage sensing via wall 270 is placed inside the inner shield part 232.

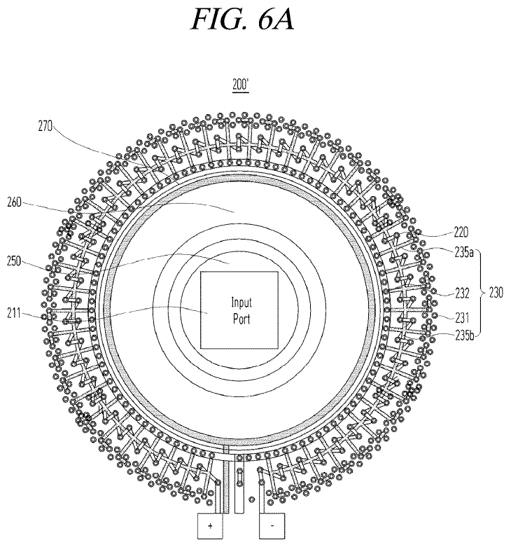

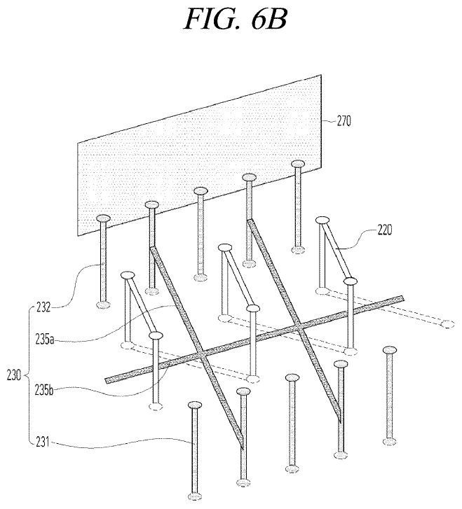

The shield part 230 also includes a shield bridge 235 formed to connect separate spaces. For example, the shield bridge 235 may be composed of a first shield bridge 235a (see FIG. 3A to FIG. 5), or may be composed of the first shield bridge 235a and a second shield bridge 235b (see FIG. 6A and FIG. 6B).

Referring to FIG. 3A, the shield part 230 includes the first shield bridge 235a. As shown in FIG. 3B, the first shield bridge 235a is formed to connect the outer shield part 231 and the inner shield part 232. The shield part 230 can remove a potential difference between the outer shield part 231 and the inner shield part 232 by using the first shield bridge 235a. Therefore, it is possible to further enhance the electrical shielding function.

Further, as shown in FIG. 4, the shield part 230 includes an upper shield part 233 and a lower shield part 234. The upper shield part 233 is formed above the Rogowski coil part 220, and the lower shield part 234 is formed below the Rogowski coil part 220. Herein, the upper shield part 233 and the lower shield part 234 are formed from jig metal or PCB conductive layer.

Referring to FIG. 4, the shield part 230 includes an opening surface 240 formed to adjust the shielding strength. The opening surface 240 may include an upper opening surface 240a and a lower opening surface 240b in contact with upper and lower sides of the inner shield part 232. The upper opening surface 240a is opened at a predetermined distance from an upper surface of the inner shield part 232, and the lower opening surface 240b is opened at a predetermined distance from a lower surface of the inner shield part 232. Herein, it is possible to adjust a space of the opening surface 240 in a height direction.

As shown in FIG. 4 and FIG. 5, the Rogowski coil current sensor 200 may adjust the shielding strength by using two or one opening surface 240. For example, the shield part 230 may have the upper opening surface 240a only as shown in FIG. 5A or may have the lower opening surface 240b only as shown in FIG. 5B. Therefore, the Rogowski coil current sensor 200 can induce a magnetic field of desired signals by using the upper opening surface 240a or the lower opening surface 240b.

That is, the shield part 230 can adjust the shielding strength by adjusting the number of opening surfaces 240 or the height of the opening surface 240. Therefore, the Rogowski coil current sensor 200 can reduce a via spacing of the outer shield part 231 or the inner shield part 232. Accordingly, the Rogowski coil current sensor 200 can shield high-frequency noise as well as low-frequency noise.

FIG. 6A is a plan view of a Rogowski coil current sensor including a second shield bridge, and FIG. 6B is an example diagram illustrating a structure of the Rogowski coil current sensor including the second shield bridge.

Referring to FIG. 6A and FIG. 6B, the shield part 230 further includes the second shield bridge 235b. That is, in a Rogowski coil current sensor 200′ according to an embodiment illustrated in FIG. 6A and FIG. 6B, the second shield bridge 235b may be placed in addition to the first shield bridge 235a to further enhance an electrical shielding effect. The second shield bridge 235b is formed to penetrate the first shield bridge 235a.

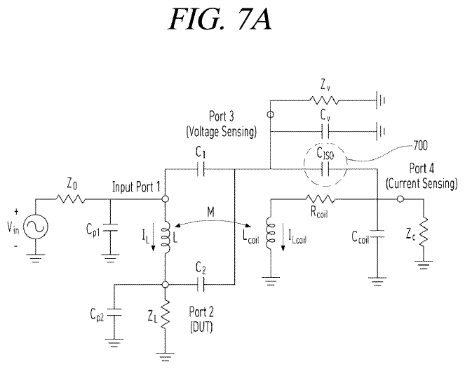

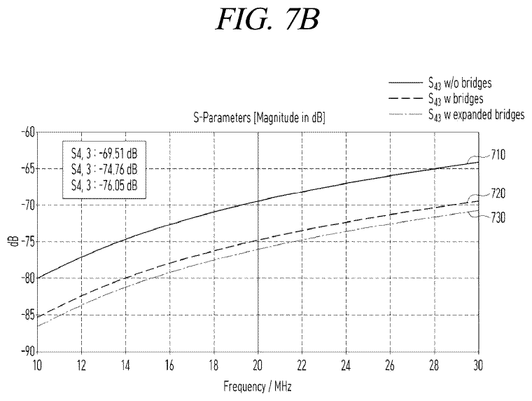

FIG. 7A shows a PCB V-I sensor equivalent circuit, and FIG. 7B shows a simulation result. As shown in FIG. 7A, when voltage sensing and current sensing are performed simultaneously, electrical coupling occurs between a voltage sensing unit and a current sensing unit. Herein, the electrical coupling can equivalently be represented as a capacitor (C_{ISO}) 700.

In the embodiment shown in FIG. 7A, when S-parameters are simulated with an input port designated as Port 1, a port connected to a measurement target device as Port 2, a voltage sensing unit output port as Port 3, and a current sensing unit output port as Port 4, stronger electrical shielding results in weaker electrical coupling between the voltage sensing unit and the current sensing unit. This is indicated by smaller values of C_{ISO} 700 and S₄₃.

In FIG. 7A, L_{coil} represents a self-inductance of the Rogowski coil, and C_{coil} represents a parasitic capacitance that occurs between multiple turns of the Rogowski coil. Further, R_{coil} represents an ohmic loss of the Rogowski coil.

Furthermore, L represents an inductance of an inner coaxial conductor, and M represents a mutual inductance between the inner coaxial conductor and the Rogowski coil. Moreover, Zᵥ represents an input impedance of the voltage sensing unit, and Z_{c} represents an input impedance of the current sensing unit.

Also, Cₚ₁ represents a capacitance between Port 1 and the grounded upper shield part 233, and Cₚ₂ represents a capacitance between Port 2 and the grounded lower shield part 234. Further, C₁ represents a capacitance between Port 1 and the voltage sensing unit, C₂ represents a capacitance between Port 2 and the voltage sensing unit, and Cy represents a capacitance between a central via 270 for voltage sensing and a ground GND.

In FIG. 7B, simulation results will be described for three cases: when there is no shield bridge (710); when a first shield bridge is included (720); and when a second shield bridge is further included (730). As shown in FIG. 7B, S₄₃ has a value of “−69.51 dB” when there is no shield bridge (710), S₄₃ has a value of “−74.76 dB” when the first shield bridge is included (720), and S₄₃ has a value of “−76.05 dB” when the second shield bridge is further included (730). This confirms that the addition of the shield bridges enhances electrical shielding.

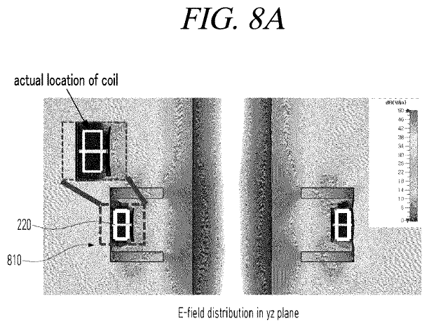

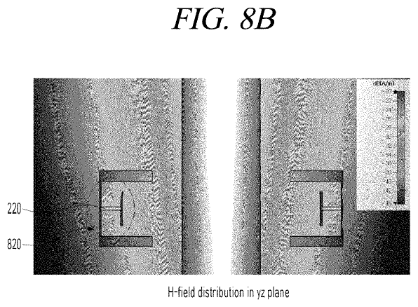

FIG. 8A is an example diagram illustrating an electric field (E-field) of a Rogowski coil current sensor, and FIG. 8B is an example diagram illustrating a magnetic field (H-field) of the Rogowski coil current sensor. Referring to FIG. 8A, an electric field shielding effect is observed in a region 810 where the Rogowski coil part 220 is located. Also, referring to FIG. 8B, it is confirmed that a magnetic field can be sensed in a region 820 where the Rogowski coil part 220 is located.

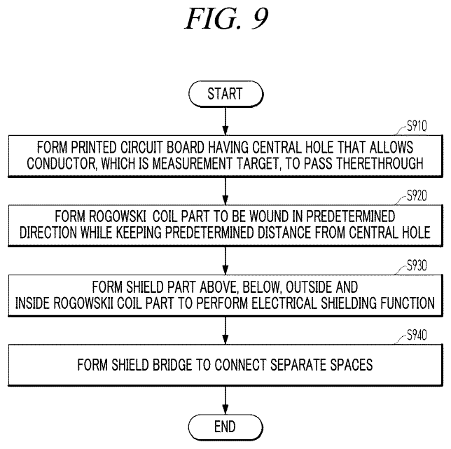

FIG. 9 is a flowchart showing a method of manufacturing a Rogowski coil current sensor. The method of manufacturing a Rogowski coil current sensor illustrated in FIG. 9 includes the processes time-sequentially performed according to the embodiment illustrated in FIG. 2 to FIG. 8. Therefore, the descriptions of the processes may also be applied to the method of manufacturing a Rogowski coil current sensor performed according to the embodiment illustrated in FIG. 2 to FIG. 8 even though they are omitted hereinafter.

In a process S910, the method of manufacturing a Rogowski coil current sensor includes a process of forming a printed circuit board (PCB) having a central hole that allows a conductor, which is a measurement target, to pass therethrough.

In a process S920, the method of manufacturing a Rogowski coil current sensor includes a process of forming a Rogowski coil part to be wound in a predetermined direction while keeping a predetermined distance from the central hole.

In a process S930, the method of manufacturing a Rogowski coil current sensor includes a process of forming a shield part above, below, outside and inside the Rogowski coil part to perform an electrical shielding function.

In a process S940, the method of manufacturing a Rogowski coil current sensor includes a process of forming a shield bridge to connect separate spaces.

In the descriptions above, the processes S910 to S940 may be divided into additional processes or combined into fewer processes depending on an embodiment. In addition, some of the processes may be omitted and the sequence of the processes may be changed if necessary.

The above description of the present disclosure is provided for the purpose of illustration, and it would be understood by those skilled in the art that various changes and modifications may be made without changing technical conception and essential features of the present disclosure. Thus, it is clear that the above-described embodiments are illustrative in all aspects and do not limit the present disclosure. For example, each component described to be of a single type can be implemented in a distributed manner. Likewise, components described to be distributed can be implemented in a combined manner.

The scope of the present disclosure is defined by the following claims rather than by the detailed description of the embodiment. It shall be understood that all modifications and embodiments conceived from the meaning and scope of the claims and their equivalents are included in the scope of the present disclosure.

### EXPLANATION OF CODES

200: Rogowski coil current sensor
210: Printed circuit board
220: Rogowski coil part
230: Shield part
235: Shield bridge

We claim:

1. A current sensor, comprising:
a printed circuit board (PCB) having a central hole that allows a conductor, which is a measurement target, to pass therethrough;
a Rogowski coil part formed to be wound in a predetermined direction while keeping a predetermined distance from the central hole; and
a shield part formed outside and inside the Rogowski coil part and configured to perform an electrical shielding function,
wherein the shield part includes a shield bridge formed to connect separate spaces.

2. The current sensor of claim 1,
wherein the shield part includes:
an upper shield part formed above the Rogowski coil part;
a lower shield part formed below the Rogowski coil part;
an outer shield part formed outside the Rogowski coil part;
an inner shield part formed inside the Rogowski coil part, and
a first shield bridge formed to connect the outer shield part and the inner shield part.

3. The current sensor of claim 2,
wherein the shield part further includes a second shield bridge formed to penetrate the first shield bridge.

4. The current sensor of claim 2,
wherein the shield part further includes an opening surface formed to adjust a shielding strength, and
a space of the opening surface in a height direction is adjustable.

5. The current sensor of claim 4,
wherein the opening surface includes:
an upper opening surface opened at a predetermined distance from an upper surface of the inner shield part; and
a lower opening surface opened at a predetermined distance from a lower surface of the inner shield part.

6. The current sensor of claim 4,
wherein the upper shield part and the lower shield part are formed from jig metal or PCB conductive layer.

7. A method of manufacturing a current sensor, comprising:
forming a printed circuit board (PCB) having a central hole that allows a conductor, which is a measurement target, to pass therethrough;
forming a Rogowski coil part to be wound in a predetermined direction while keeping a predetermined distance from the central hole; and
forming a shield part above, below, outside and inside the Rogowski coil part to perform an electrical shielding function,
wherein the forming the shield part includes forming a shield bridge to connect separate spaces.

8. The method of manufacturing a current sensor of claim 7,
wherein the forming the shield part includes:
forming an upper shield part above the Rogowski coil part;
forming a lower shield part below the Rogowski coil part;
forming an outer shield part outside the Rogowski coil part;
forming an inner shield part inside the Rogowski coil part, and
forming a first shield bridge to connect the outer shield part and the inner shield part.

9. The method of manufacturing a current sensor of claim 8,
wherein the forming the shield part further includes forming a second shield bridge to penetrate the first shield bridge.

10. The method of manufacturing a current sensor of claim 8,
wherein the forming the shield part further includes forming an opening surface to adjust a shielding strength, and
a space of the opening surface in a height direction is adjustable.
